(19) United States
(12) Patent Application Publication
(10) Pub. No.: US 2017/0324004 A1
(43) Pub. Date: Nov. 9, 2017

(54) LIGHT-EMITTING DEVICE AND LIGHTING SYSTEM

(71) Applicant: LG INNOTEK CO., LTD., Seoul (KR)

(72) Inventors: Eun Hyung LEE, Seoul (KR); Yoo Hwan KANG, Seoul (KR); Won Ho KIM, Seoul (KR); Tae Ki KIM, Seoul (KR); Sungwon David ROH, Seoul (KR); Hyo Jung MOON, Seoul (KR); Yong Han JEON, Seoul (KR)

(73) Assignee: LG INNOTEK CO., LTD., Seoul (KR)

(21) Appl. No.: 15/528,058

(22) PCT Filed: Oct. 29, 2015
(86) PCT No.: PCT/KR2015/011473

§ 371 Date: May 18, 2017

(30) Foreign Application Priority Data
Nov. 18, 2014 (KR) 10-2014-0160839

(51) Int. Cl. H01L 33/38; H01L 33/30; H01L 33/40; H01L 33/46

(52) U.S. Cl. CPC H01L 33/387; H01L 33/382; H01L 33/30; H01L 33/46; H01L 33/405

(57) ABSTRACT

Disclosed is a light emitting device according to the embodiment including a conductive semiconductor layer divided into at least two or more light emitting regions; a plurality of light emitting structures on the conductive semiconductor layer; an electrode layer on the plurality of light emitting structures; a second electrode electrically connected to the electrode layer; and a first electrode electrically connected to the conductive semiconductor layer, wherein each of the light emitting structures includes a rod-shaped first conductivity type semiconductor, an active layer configured to surround the first conductivity type semiconductor and a second conductivity type semiconductor configured to surround the active layer, and each of the light emitting structures has at least two or more outer surfaces having different extending directions with respect to an upper surface of the conductive semiconductor layer.

### TECHNICAL FIELD

The embodiment relates to a light emitting device, a manufacturing method of the light emitting device, a light emitting device package and a lighting system, and more particularly, to a light emitting device having a rod-shaped light emitting structure.

### BACKGROUND ART

A light emitting device is a p-n junction diode having a characteristic in which electric energy is converted into light energy, may be configured with a compound semiconductor of Group III and Group V elements or the like on the periodic table and may represent various colors by adjusting a composition ratio of the compound semiconductor.

In the light emitting device, when a forward voltage is applied, electrons of an n layer are combined with holes of a p layer, and energy corresponding to band gap energy between a conduction band and a valence band may be generated, and the energy is mainly emitted in the form of heat or light, and when emitted in the form of light, serves as a light emitting device.

For example, a nitride semiconductor is receiving a lot of attention in an optical device and a high-output electronic device development field due to high thermal stability and wide band gap energy thereof. In particular, a blue light emitting device, a green light emitting device and an UV light emitting device using the nitride semiconductor are commercialized and used widely.

Recently, as demand for high-efficiency LEDs is increased, improvement in brightness becomes an issue.

Particularly, in the case of a light emitting structure which directly emits light, methods which break from a simple stacked type epitaxial structure and improve the brightness through various structural changes are proposed.

At this point, as an improvement direction of the light emitting structure, it is required that crystal quality of a semiconductor layer is improved, a light emitting region expands, and generated light is effectively emitted to an outside of the light emitting structure.

Meanwhile, a white light emitting device using a semiconductor may be manufactured by using all of red, green and blue light emitting devices, but there are some disadvantages that a manufacturing cost is high and a size of a product is large because a driving circuit is complicated.

### DISCLOSURE

### Technical Problem

The embodiment is directed to providing a light emitting device which is capable of enhancing brightness while providing white light with high color rendering property, a manufacturing method of the light emitting device, a light emitting device package and a lighting system.

### Technical Solution

One aspect of the present invention provides a light emitting device including a conductive semiconductor layer divided into at least two or more light emitting regions; a plurality of light emitting structures on the conductive semiconductor layer; an electrode layer on the plurality of light emitting structures; a second electrode electrically connected to the electrode layer; and a first electrode electrically connected to the conductive semiconductor layer, wherein each of the light emitting structures includes a rod-shaped first conductivity type semiconductor, an active layer configured to surround the first conductivity type semiconductor and a second conductivity type semiconductor configured to surround the active layer, and each of the light emitting structures has at least two or more outer surfaces having different extending directions with respect to an upper surface of the conductive semiconductor layer.

Another aspect of the present invention provides a light emitting device including a conductive semiconductor layer divided into at least two or more light emitting regions; a plurality of light emitting structures having rod shapes on the conductive semiconductor layer; an electrode layer on the plurality of light emitting structures; a second electrode electrically connected to the electrode layer; and a first electrode electrically connected to the conductive semiconductor layer, wherein the light emitting structures included in the light emitting regions of the conductive semiconductor layer have different electric fields and emit light of different wavelength bands when being operated.

### Advantageous Effects

According to the embodiment, it is possible to provide a light emitting device having an optimal structure for enhancing brightness, a manufacturing method of the light emitting device, a light emitting device package and a lighting system.

In the light emitting structure of the embodiment, a contact surface area between an active layer and a semiconductor layer can be greatly increased as compared to a stacked type nano-rod structure, and thus the light emitting efficiency can be considerably enhanced, and an area in which light resonates can also be increased.

Also, the light emitting structure also has a small area which is in contact with a substrate interface when grown on the substrate, and thus probability of occurrence of TDD can be reduced, and it is advantageous in improving quality of the active layer.

And in the light emitting structure of the embodiment, when light is emitted from the active layer to a side surface of the light emitting structure, light extraction efficiency can also be improved due to an angular shape on the side surface of the light emitting structure.

Particularly, the embodiment can emit light of various wavelength bands without adding a separate component in a single light emitting device and thus can emit white light of high color rendering property.

Also, according to the embodiment, it is possible to provide a light emitting device having improved light emitting efficiency by combining holes and electrons throughout a plurality of quantum wells, a manufacturing method of the light emitting device, a light emitting device package and a lighting system.

Also, according to the embodiment, it is possible to improve the quality of the active layer, thereby reducing an operating voltage and thus improving reliability and reproducibility.

And according to the embodiment, it is possible to provide a light emitting device capable of improving a quantum confinement effect, a light emitting efficiency and device reliability, a manufacturing method of the light emitting device, a light emitting device package and a lighting system.

### DESCRIPTION OF DRAWINGS

FIG. 1 is a plan view of a light emitting device according to an embodiment.

FIG. 2 is a cross-sectional view taken along line A-A of FIG. 1.

FIG. 3 is a plan view of a light emitting device according to another embodiment.

FIG. 4 is a perspective view of a lower portion of a light emitting structure of the embodiment.

FIG. 5 is a perspective view of a lower portion of a light emitting structure of another embodiment.

FIG. 6 is a perspective view of an upper portion of the light emitting structure of the embodiment.

FIG. 7 is a cross-sectional view of the upper portion of the light emitting structure of the embodiment.

FIG. 8 is a perspective view of an upper portion of the light emitting structure of another embodiment.

FIG. 9 is a cross-sectional view of the upper portion of the light emitting structure of another embodiment.

FIG. 10 is a side cross-sectional view of a first light emitting region according to a first embodiment.

FIG. 11 is a side cross-sectional view of a second light emitting region according to the first embodiment.

FIG. 12 is a side cross-sectional view of a first light emitting region according to a second embodiment.

FIG. 13 is a side cross-sectional view of a second light emitting region according to the second embodiment.

FIG. 14 is a side cross-sectional view of a third light emitting region.

FIG. 15 is a side cross-sectional view of a first light emitting region according to a third embodiment.

FIG. 16 is a side cross-sectional view of a second light emitting region according to the third embodiment.

FIG. 17 is a side cross-sectional view of a third light emitting region according to the third embodiment.

FIG. 18 is a side cross-sectional view of a first light emitting region according to a fourth embodiment.

FIG. 19 is a side cross-sectional view of a second light emitting region according to the fourth embodiment.

FIG. 20 is a side cross-sectional view of a third light emitting region according to the fourth embodiment.

### MODES OF THE INVENTION

In the description of embodiments, it will be understood that when a layer (or film), region, pattern or structure is referred to as being “on/over” or “under” another layer (or film), region, pattern or structure, the terminologies of “on/over” and “under” include both the meanings of “directly” or “by interposing another layer (indirectly)”. Further, the reference about “on/over” and “under” each layer will be made on the basis of drawings.

A white light emitting device can be realized by adding a yellow phosphor, to a blue light emitting device. However, when white light is formed by mixing only two colors of light, there is a problem that light of a certain wavelength band is not included, resulting in low color rendering property. To solve the problem, a method of adding a red phosphor has been proposed, but the red phosphor is expensive, and efficiency of the phosphor according to wavelength conversion is deteriorated.

Embodiments modify a structure of a light emitting device without adding any additional components such as a phosphor to emit light of a desired wavelength band in a single light emitting device and also to emit light of various wavelength bands in the single light emitting device, thereby proposing a light emitting device capable of emitting white light with high efficiency and high color rendering property.

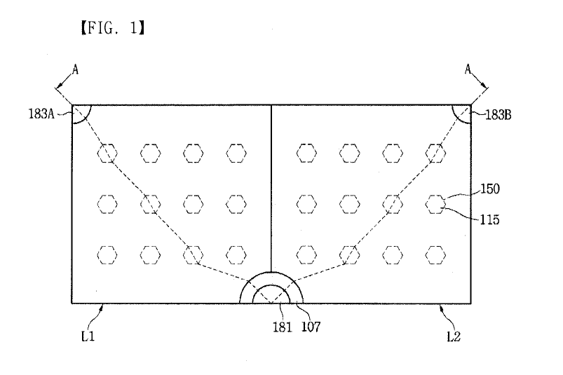

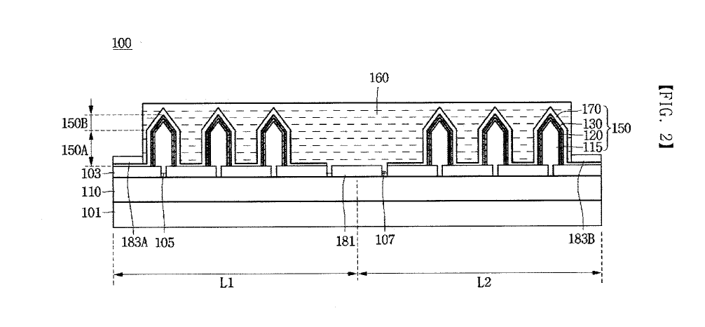

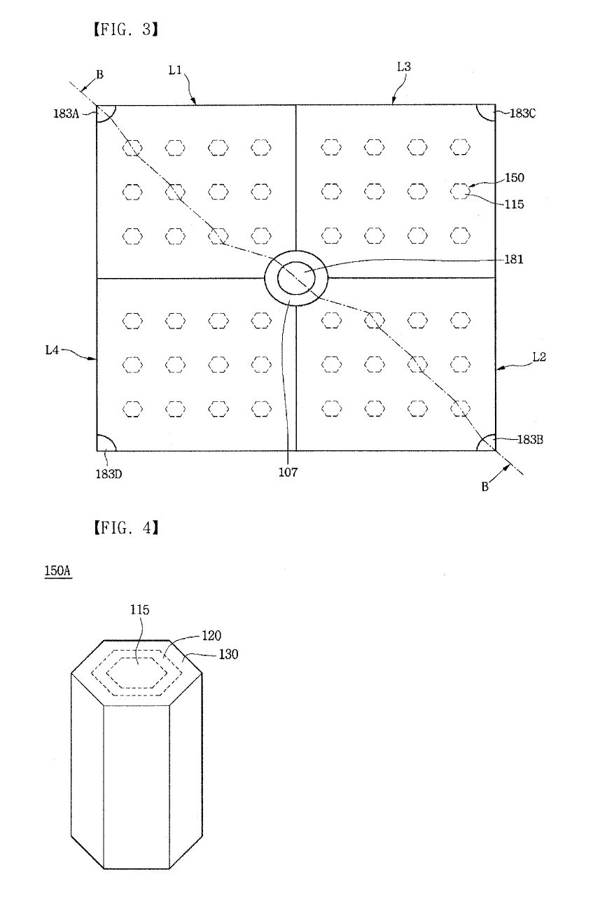

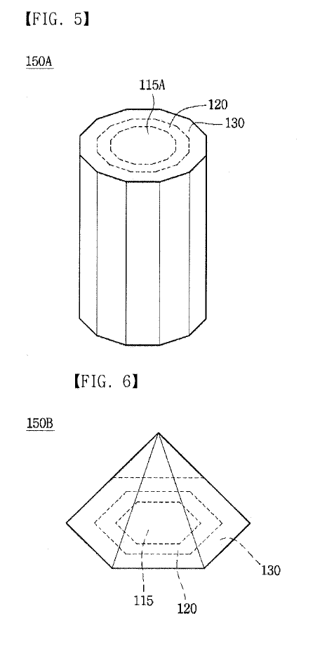

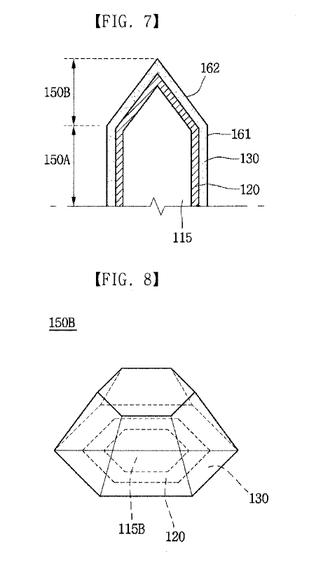

FIG. 1 is a plan view of a light emitting device according to an embodiment, FIG. 2 is a cross-sectional view taken along line A-A of FIG. 1, FIG. 3 is a plan view of a light emitting device according to another embodiment, FIG. 4 is a perspective view of a lower portion of a light emitting structure of the embodiment, FIG. 5 is a perspective view of a lower portion of a light emitting structure of another embodiment, FIG. 6 is a perspective view of an upper portion of the light emitting structure of the embodiment, FIG. 7 is a cross-sectional view of the upper portion of the light emitting structure of the embodiment, FIG. 8 is a perspective view of an upper portion of the light emitting structure of another embodiment, and FIG. 9 is a cross-sectional view of the upper portion of the light emitting structure of another embodiment.

Hereinafter, a light emitting device 100 according to an embodiment will be described with reference to FIGS. 1 to 9.

Referring to FIGS. 1 and 2, the light emitting device 100 according to the embodiment may include a substrate 101, a conductive semiconductor layer 110 on the substrate 101, a plurality of light emitting structures 150 on the conductive semiconductor layer 110, an electrode layer 170 on the light emitting structures 150, second electrodes 183A and 183B on the electrode layer 170, and a first electrode 181 on the conductive semiconductor layer 110. And the light emitting structure 150 may include a first conductivity type semiconductor 115, an active layer 120 on the first conductivity type semiconductor 115, and a second conductivity type semiconductor 130 on the active layer 120.

In FIG. 1, the light emitting device 100 according to the embodiment may be divided into at least two light emitting regions in a top view. A criterion for distinguishing the light emitting regions of the light emitting device 100 may be a wavelength band of light emitted from each of the light emitting regions. That is, in the embodiment, the light emitting device 100 may be divided into a first light emitting region L1 which emits light of a first wavelength band and a second light emitting region L2 which emits light of a second wavelength band when seen in the top view.

The light emitting regions may be regularly divided to have the same areas and may also be irregularly divided into random areas, unlike as shown in FIG. 1.

Each of the light emitting regions may include the light emitting structures 150 having the same structures and may share the substrate 101, the conductive semiconductor layer 110 and the first electrode 181, but the present invention is not limited thereto. FIGS. 1 and 2 have illustrated that the second electrodes 183A and 183B are arranged in the first light emitting region L1 and the second light emitting region L2, respectively. However, the first light emitting region L1 and the second light emitting region L2 may share the second electrodes 183A and 183B, like the first electrode 181.

As shown in FIG. 3, a light emitting device 100 according to another embodiment may be divided into four regions in a top view, and each of the regions may emit light of different wavelength band. That is, in another embodiment, the light emitting device 100 may be divided into a first light emitting region L1 which emits light in a first wavelength band, a second light emitting region L2 which emits light in a second wavelength band, a third light emitting region L3 which emits light of a third wavelength band, and a fourth light emitting region which emits light of a fourth wavelength band when seen in the top view. Even in another embodiment, each of the light emitting regions may include the light emitting structures 150 having the same structures and may share the substrate 101, the conductive semiconductor layer 110 and the first electrode 181. FIG. 3 has illustrated that second electrodes 183A, 183B, 183C and 183D are arranged in the light emitting regions, respectively. However, the light emitting regions may share the second electrodes 183A, 183B, 183C and 183D, like the first electrode 181.

Hereinafter, a principle that the first light emitting region L1 and the second light emitting region L2 emit light of different wavelength bands will be described together with a description of each configuration of the light emitting device 100.

First, the light emitting device 100 of the embodiment may include the substrate 101.

The substrate 101 may be a substrate formed of a conductive or insulating material, or a substrate formed of a light-transmitting or non-light-transmitting material. The substrate 101 may be selected from the group consisting of a sapphire substrate (Al₂O₃), GaN, SiC, ZnO, Si, GaP, InP, Ga₂O₃, GaAs and so on. The substrate 101 may be used as a layer for supporting the light emitting device 100.

A compound semiconductor layer of Group II to Group VI elements may be disposed on the substrate 101. At least one of a nitride buffer layer (not shown) and an undoped semiconductor layer (not shown) may be disposed between the substrate 101 and the conductive semiconductor layer 110. The buffer layer and the undoped semiconductor layer may be disposed as compound semiconductors of Group III-V elements, and the buffer layer serves to reduce a difference in a lattice constant with respect to the substrate 101, and the undoped semiconductor layer may be disposed as a GaN-based semiconductor which is not doped.

The conductive semiconductor layer 110 may be disposed as a compound semiconductor of Group II to Group VI elements, and may be formed of, for example, at least one of GaN, AlN, AlGaN, InGaN, InN, InAlGaN, AlInN, AlGaAs, GaP, GaAs, GaAsP, AlGaInP and so on. The conductive semiconductor layer 110 is a layer for forming a rod-type first conductivity type semiconductor 115 and may be formed of a compound semiconductor of Group III-V elements, for example, GaN. A single-layered or a multilayered conductive semiconductor layer 110 may be provided, but the present invention is not limited thereto.

And the conductive semiconductor layer 110 may include a first conductive dopant. The first conductive dopant includes an n-type dopant, for example, a dopant such as Si, Ge, Sn, Se and Te. The conductive semiconductor layer 110 may be included in the light emitting structures 150 as a first conductivity type semiconductor, but the present invention is not limited thereto.

A mask layer 103 may be disposed on the conductive semiconductor layer 110. The mask layer 103 has a plurality of holes 105. The rod type light emitting structures 150 are disposed in the holes 105. The mask layer 103 may be formed of an insulating material and may be formed of, for example, at least one of SiO₂, SiOₓ, SiOₓN_{y}, Si₃N₄ and Al₂O₃. The plurality of holes 105 may be spaced apart from each other and may be arranged, for example, at regular intervals, irregular intervals, or random intervals. Each of the holes 105 may be formed in a circular shape, an elliptical shape, or a polygonal shape when seen in a top view, and a rod shape of the first conductivity type semiconductor 115 may be determined according to such a shape of the hole 105.

The first conductivity type semiconductor 115 of the light emitting structure 150 is disposed on the hole 105.

The light emitting structure 150 includes the first conductivity type semiconductor 115, the active layer 120 and the second conductivity type semiconductor 130. The light emitting structure 150 may further include the conductive semiconductor layer 110, but the present invention is not limited thereto.

The first conductivity type semiconductor 115 includes a composition formula of InₓAl_{y}Ga_{1-x-y}N (0≦x≦1, 0<y≦1, 0≦x+y≦1). The first conductivity type semiconductor 115 may include a compound semiconductor of Group III-V elements which is doped with the first conductive dopant, for example, at least one or more of GaN, AlN, AlGaN, InGaN, InN, InAlGaN, AlInN, AlGaAs, GaP, GaAs, GaAsP, AlGaInP and so on. For example, the first conductivity type semiconductor 115 may include GaN having a vertical rod shape. GaN may be selectively grown in a vertical direction (0001 direction), a Facet direction, or a horizontal direction according to a shape of the hole 105 of the mask layer 103 and growth conditions. In the embodiment, for example, GaN may be formed in a vertical rod shape.

In the embodiment, the rod shape of the first conductivity type semiconductor 115 may be formed in a polygonal column shape as shown in FIGS. 4 and 5, for example, a hexagonal column shape as shown in FIG. 4 and a dodecagonal column shape as shown in FIG. 5. At this time, a lower portion of the first conductivity type semiconductor 115 may extend vertically from the conductive semiconductor layer 110. And an upper portion of the first conductivity type semiconductor 115 may extend upward from the conductive semiconductor layer 110 at a predetermined angle. For example, the lower portion of the first conductivity type semiconductor 115 may have a hexagonal column shape, and the upper portion of the first conductivity type semiconductor 115 may have a hexagonal pyramid shape which extends from the lower portion.

The first conductivity type semiconductor 115 may include the first conductive dopant, for example, the n-type dopant such as Si, Ge, Sn, Se and Te. The first conductivity type semiconductor 115 may be formed as a single layer or a multilayer, but the present invention is not limited thereto.

The rod shape of the first conductivity type semiconductor 115 may have a diameter within a range of 5 nm<diameter<5 μm. Specifically, the rod shape of the first conductivity type semiconductor 115 may have a diameter within a range of 10 nm<diameter<2 μm. More specifically, the rod shape of the first conductivity type semiconductor 115 may have a diameter within a range of 50 nm<diameter<1 μm.

When the diameter of the rod is 2 μm or more, an area of the active layer 120 is not increased in proportion to the rod diameter, and a growth rate of the active layer 120 or the second conductivity type semiconductor 130 may be lowered, and improvement of quantum efficiency is also insignificant. Also, when the diameter of the rod is 5 nm or less, there is a difficulty in manufacturing the hole 105 of the mask layer 103 or growth through the hole 105.

The rod shape of the first conductivity type semiconductor 115 may have a height within a range of 10 nm<height<5 μm, for example, a range of 1 μm<height <3 μm. When the height of the rod is 5 μm or more, an injection distance of a carrier and mobility of the carrier are lowered, and rod growth is difficult. When the height of the rod is 10 nm or less, there is a problem that the injection distance of the carrier, the mobility of the carrier and a light emitting area are not improved as compared with a horizontal LED chip.

Since the rod-shaped first conductivity type semiconductor 115 according to the embodiment has a plurality of side surfaces and upper surfaces and faces the active layer 120, an area of the active layer 120 may be increased. Also, since the rod-shaped first conductivity type semiconductor 115 is disposed on the conductive semiconductor layer 110, a defect density propagated from the substrate 101 may be reduced, and thus crystal quality of the active layer 120 may be improved.

A reflective layer (not shown) may be further disposed between the first conductivity type semiconductor 115 and the active layer 120. The reflective layer may include a distributed Bragg reflector (DBR) layer which is a plurality of semiconductor layers (e.g., two layers) having different refractive indices. The DBR has the different refractive indices and thus may reflect light which is emitted from the active layer 120 toward the first conductivity type semiconductor 115. In the embodiment, all of the semiconductor layers forming the reflective layer may include the first conductive dopant. The first conductive dopant may be an n-type dopant, for example, a dopant such as Si, Ge, Sn, Se and Te. The reflective layer may pass carriers generated in the first conductivity type semiconductor 115 to the active layer 120 and may inject carriers generated in the reflective layer itself into the active layer 120, thereby improving the light emitting efficiency. The reflective layer may reflect the light emitted from the active layer 120 toward the first conductivity type semiconductor 115, thereby improving optical efficiency. In particular, the reflective layer may drastically reduce a light absorption rate of the first conductivity type semiconductor 115 in the light emitting device 100 which emits light of a wavelength band of 400 nm or less.

Meanwhile, the active layer 120 may be disposed on the first conductivity type semiconductor 115. Specifically, the active layer 120 may be disposed to surround the first conductivity type semiconductor 115. The active layer 120 may be disposed on a plurality of side surfaces and a plurality of upper surfaces of a first semiconductor layer. The active layer 120 includes a plurality of side surfaces and a plurality of upper surfaces, and the plurality of side surfaces and the plurality of upper surfaces may face respectively the plurality of side surfaces and the plurality of upper surfaces of the first conductivity type semiconductor 115.

The active layer 120 selectively includes a single quantum well, a multiple quantum well (MQW), a quantum wire structure or a quantum dot structure. The active layer 120 includes a period of a well layer and a barrier layer. The well layer may include a composition formula of InₓAl_{y}Ga_{1-x-y}N (0≦x≦1, 0≦y≦1, 0≦x+y≦1), and the barrier layer may include a composition formula of InₓAl_{y}Ga_{1-x-y}N (0≦x≦1, 0≦y≦1, 0≦x+y≦1). The period of the well layer/the barrier layer may be realized, for example, with a pair of InGaN/GaN, InGaN/AlGaN, InGaN/InGaN, GaN/AlGaN, InAlGaN/InAlGaN, AlGaAs/GaAs, InGaAs/GaAs, InGaP/GaP, AlInGaP/InGaP or InP/GaAs. The period of the well layer/the barrier layer may be formed in two or more periods, and the barrier layer may be formed of a semiconductor material having a band gap wider than that of the well layer. The active layer 120 may selectively emit light within a wavelength range from a visible ray to an ultraviolet ray and may emit, for example, light having a peak wavelength of the visible ray or light having a blue peak wavelength, but the present invention is not limited thereto.

The second conductivity type semiconductor 130 may be disposed to surround the active layer 120. The second conductivity type semiconductor 130 may include a plurality of side surfaces and upper surfaces and may face the side surfaces and upper surfaces of the active layer 120.

The second conductivity type semiconductor 130 includes a semiconductor which is doped with a second conductive dopant, for example, a composition formula of InₓAl_{y}Ga_{1-x-y}N (0≦x≦1, 0≦y≦1, 0≦x+y≦1916 ). The second conductivity type semiconductor 130 may be configured with at least one of compound semiconductors such as GaN, InN, AlN, InGaN, AlGaN, InAlGaN, AlInN, AlGaAs, GaP, GaAs, GaAsP, and AlGaInP. When the active layer 120 emits light of an ultraviolet wavelength band, the second conductivity type semiconductor 130 may be formed to include AlGaN. And the second conductivity type semiconductor 130 may be a p-type semiconductor layer, and the second conductive dopant may be a p-type dopant and may include Mg, Zn, Ca, Sr and Ba.

Hereinafter, the light emitting structure 150 will be described focusing on a shape thereof with reference to FIGS. 2 and FIGS. 4 to 8.

The light emitting structure 150 has a rod shape. Specifically, the light emitting structure 150 may have at least two or more outer surfaces which extend at different angles with respect to an upper surface of the conductive semiconductor layer 110 when seen in a side cross section.

For example, the light emitting structure 150 may include a first outer surface 161 (in FIG. 7) which extends vertically from the upper surface of the conductive semiconductor layer 110 and a second outer surface 162 (in FIG. 7) which extends from the upper surface of the conductive semiconductor layer 110 at a predetermined angle.

Referring to FIG. 2, a lower portion 150A of the light emitting structure 150 may have a rod shape which extends vertically. For example, the lower portion 150A of the light emitting structure 150 of the embodiment may have the hexagonal column shape as shown in FIG. 4.

In another embodiment, the lower portion 150A of the light emitting structure 150 may have the dodecagonal column shape as shown in FIG. 5.

Therefore, in each of the embodiments, the outer surface of the lower portion 150A of the light emitting structure 150 may be perpendicular to the upper surface of the conductive semiconductor layer 110.

An upper portion 150B of the light emitting structure 150 may be tilted from the upper surface of the conductive semiconductor layer 110 at a predetermined angle and may extend upward. For example, the upper portion 150B of the light emitting structure 150 of the embodiment may have a hexagonal pyramid shape as shown in FIGS. 6 and 7. Therefore, an outer surface of the upper portion 150B of the light emitting structure 150 may be at a predetermined angle with respect to the upper surface of the conductive semiconductor layer 110.

Therefore, as shown in FIG. 7, the light emitting structure 150 of the embodiment may include the first outer surface 161 at the lower portion 150A thereof and may also include the second outer surface 162 at the upper portion 150B thereof.

As described above, the active layers 120 included in the outer surfaces 161 and 162 which are grown from the upper surface of the conductive semiconductor layer 110 in different extension directions may have different thicknesses. That is, the active layer 120 included in the first outer surface 161 (e.g., the active layer 120 included in the lower portion 150A of the light emitting structure) and the active layer 120 included in the second outer surface 162 (e.g., the active layer 120 included in the upper portion 150B of the light emitting structure) may have different thicknesses. As the first conductivity type semiconductor 115 is grown in the different extension directions, an outer crystal surface of the first conductivity type semiconductor 115 of the first outer surface 161 and an outer crystal surface of the first conductivity type semiconductor of the second outer surface 162 are formed in different directions. Therefore, the growth rates of the active layers 120 growing on different crystal surfaces are different from each other, and thus the thickness of the active layer 120 may be changed according to each of the outer surfaces.

And in the embodiment, the active layer 120 included in the first outer surface 161 and the active layer 120 included in the second outer surface 162 may have a different composition of In. As described above, since the outer surface of the first semiconductor layer of the first outer surface 161 and the outer surface of the first semiconductor layer of the second outer surface 162 have the crystal surfaces different from each other, the growth rates of the active layers 120 growing on the different crystal surfaces are also different from each other, and thus the active layer 120 included in each of the outer surfaces may have the different composition of In.

Therefore, since the active layer 120 of the first outer surface 161 and the active layer 120 of the second outer surface 162 have the different compositions of In, the first outer surface 161 and the second outer surface 162 of the light emitting structure 150 may emit light of different wavelength bands. For example, the first outer surface 161 of the light emitting structure 150 may emit blue light due to a low composition of In. And the second outer surface 162 of the light emitting structure 150 may emit light of a green, yellow or red wavelength band due to a high composition of In.

In another embodiment, the upper portion 150B of the light emitting structure 150 may have a hexagonal pyramid shape of which a vertex portion is cut horizontally as shown in FIGS. 8 and 9. Therefore, the outer surface of the upper portion 150B of the light emitting structure 150 may further include a second outer surface 162 which is at a predetermined angle with respect to the upper surface of the conductive semiconductor layer 110 and a third outer surface 163 which is in parallel with the conductive semiconductor layer 110.

Even in another embodiment, the active layer 120 included in the first outer surface 161, the active layer 120 included in the second outer surface 162 and the active layer 120 included in the third outer surface 163 may have different compositions of In, as described above. As described above, since the first conductivity type semiconductor 115B of the first outer surface 161, the first conductivity type semiconductor 115B of the second outer surface 162 and the first conductivity type semiconductor 115B of the third outer surface 163 have the crystal surfaces different from each other, the growth rates of the active layers 120 growing on the different crystal surfaces are different from each other, and thus the active layers 120 included in the outer surfaces may have different compositions of In.

Therefore, the first outer surface 161, the second outer surface 162 and the third outer surface 163 have the different compositions of In and thus may emit light of different wavelength bands. For example, the active layer 120 of the first outer surface 161 of the light emitting structure 150 may emit blue light due to a low composition of In. And the active layer 120 of the third outer surface 163 of the light emitting structure 150 may emit red light due to a high composition of In. And the active layer 120 of the third outer surface 162 has a middle composition of In between those in the active layers 120 of the first outer surface 161 and the second outer surface 162 and thus may emit green or yellow light.

Since the outer surfaces of the light emitting structure 150 emit light of different wavelength bands, the emitting outer surfaces may be selected according to an applied voltage, and the light emitting structure 150 may emit light of the different wavelength bands.

Therefore, the embodiment may divide the light emitting region of the light emitting device 100, may apply different voltages thereto and thus may allow the single light emitting device 100 to emit light of various wavelength bands. In the embodiment, since the embodiment does not require a separate wavelength conversion process, high optical efficiency may be obtained, and the light of various wavelength bands may be realized in the single light emitting device 100, and thus white light having high color rendering property may be realized.

In a method of applying a different voltage to each of the light emitting regions in the light emitting device 100, voltages applied to the second electrodes 183A and 183B respectively disposed in the light emitting regions may be different, sizes of the second electrodes 183A and 183B respectively disposed in the light emitting regions may be different, and a structure, a material or the like of the electrode layer 170 may be different.

As shown in FIG. 2, the electrode layer 170 may be disposed on the rod-shaped light emitting structure 150. The electrode layer 170 may cover a plurality of rod-shaped light emitting structures 150. Specifically, the electrode layer 170 may be disposed on an upper surface of the second conductivity type semiconductor 130. The electrode layer 170 may be formed according to an external shape of the second conductivity type semiconductor 130, but the present invention is not limited thereto.

And the electrode layer 170 may be disposed on the mask layer 103 disposed between the light emitting structures 150. Accordingly, the electrode layer 170 may electrically connect the plurality of light emitting structures 150. However, the electrode layer 170 may be separately disposed at each of the light emitting regions, and the light emitting structures 150 disposed at the light emitting regions different from each other may not be electrically connected by the electrode layer 170.

In the embodiment, the electrode layer 170 may be selected from a light-transmitting material and a metallic material and may include at least one of, for example, indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IrOx, RuOx, RuOx/ITO, Ni/IrOx/Au, and Ni/IrOx/Au/ITO but is not limited to the materials. The electrode layer 170 may be formed of a metallic material which does not transmit light but reflects the light, but the present invention is not limited thereto.

Meanwhile, an insulating layer 160 may be disposed on a region between the plurality of light emitting structures 150. The insulating layer 160 may be disposed between the plurality of light emitting structures 150 and on the electrode layer 170. The insulating layer 160 may be in contact with a periphery of the electrode layer 170. In the embodiment, the insulating layer 160 may include at least one of SiO₂, SiOₓ, SiOₓN_{y}, Si₃N₄ and Al₂O₃.

The first electrode 181 may be electrically connected to at least one of the conductive semiconductor layer 110 and the first conductivity type semiconductor 115 or may be in contact therewith. The first electrode 181 may be, for example, disposed on a contact portion 112 of the conductive semiconductor layer 110. The contact portion 112 of the conductive semiconductor layer 110 may protrude further than other regions, but the present invention is not limited thereto. In another embodiment, the contact portion 112 may be formed in a groove shape.

The first electrode 181 may include an electrode pad and may be formed in a predetermined pattern, but the present invention is not limited thereto. The first electrode 181 may be branched into an arm structure for current spreading. The first electrode 181 may include a single metal of, for example, Ti, Al, In, Ta, Pd, Co, Ni, Si, Ge, Ag and Au, or an alloy thereof and may be formed as a single layer or a multilayer.

As shown in FIG. 2, the first electrode 181 may be disposed to be shared by all of the light emitting regions, but the present invention is not limited thereto.

The second electrodes 183A and 183B may be electrically connected to at least one of the electrode layer 170 and the second conductivity type semiconductor 130 or may be in contact therewith. The second electrodes 183A and 183B may be disposed on one side of the electrode layer 170. The second electrodes 183A and 183B may include at least one or more electrode pads and may be formed in a predetermined pattern, but the present invention is not limited thereto. Each of the second electrodes 183A and 183B may be branched into an arm structure for current spreading. Each of the second electrodes 183A and 183B include a single metal of, for example, Ti, Al, In, Ta, Pd, Co, Ni, Si, Ge, Ag and Au, or an alloy thereof and may be formed as a single layer or a multilayer.

As shown in FIG. 2, the second electrodes 183A and 183B may be disposed at each of the light emitting regions, but the present invention is not limited thereto. Unlike FIG. 2, the second electrodes 183A and 183B may also be shared by the plurality of light emitting regions, like the first electrode 181.

The light emitting area and the light emitting efficiency may be enhanced by the light emitting structure 150 which includes the rod-shaped first conductivity type semiconductor 115/the reflective layer/the active layer 120/the second conductivity type semiconductor 130. And the rod-shaped light emitting structure 150 of the embodiment may prevent light absorption of the first conductivity type semiconductor 115 by the reflective layer and may improve the optical efficiency. Also, it is possible to block the defect density propagated from the substrate 101, thereby preventing degradation of the crystal quality of the active layer 120 and improving internal quantum efficiency. Further, when light is emitted through the side surface and the upper surface of the light emitting structure 150, the light extraction efficiency may also be improved due to an angular shape of the light emitting structure 150.

In another embodiment, the first conductivity type semiconductor 115 of the light emitting structure 150 may be a p-type semiconductor layer, and the second conductivity type semiconductor 130 may be an n-type semiconductor layer, but the present invention is not limited thereto.

As described above, since the light emitting structure 150 has at least two or more outer surfaces and separately applies different voltages to the light emitting regions of the light emitting device 100, the single light emitting device 100 may emit light of various wavelength bands.

Hereinafter, the light emitting device 100 capable of emitting light of various wavelength bands by applying different voltages to the light emitting regions will be described through various embodiments in which the electrode layer 170 or the second electrodes 183A and 183B are modified. At this time, the same reference numerals may be assigned to configurations having similar characteristics in the description of various embodiments.

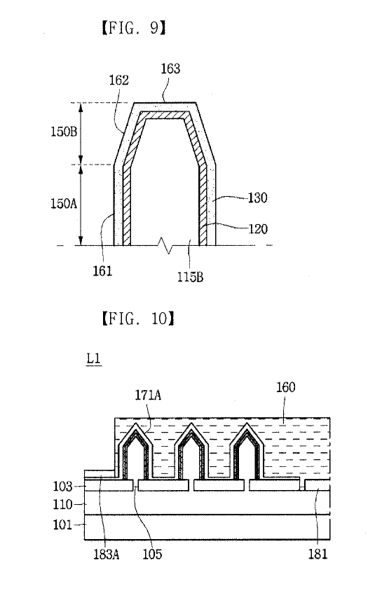

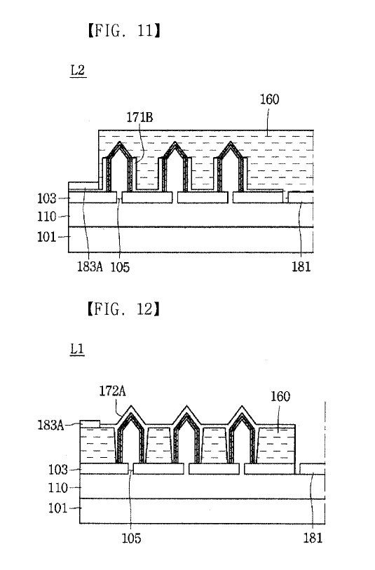

FIG. 10 is a side cross-sectional view of a first light emitting region L1 according to a first embodiment, and FIG. 11 is a side cross-sectional view of a second light emitting region L2 according to the first embodiment.

Referring to FIGS. 10 and 11, an electrode layer 171 of the first embodiment may have a different structure for each of the light emitting regions and thus may emit light of a different wavelength band in each of the light emitting regions. The electrode layer 171 of the first embodiment may include a first electrode layer 171A included in the first light emitting region L1 and a second electrode layer 171B included in the second light emitting region L2.

In FIG. 10, the first electrode layer 171A included in the first light emitting region L1 may be disposed on the light emitting structure 150 disposed on the first light emitting region L1. Specifically, the first electrode layer 171A may be disposed to surround the light emitting structure 150. At this point, the first electrode layer 171A may be disposed to cover the entire light emitting structure 150 from the lower portion 150A to the upper portion 150B. And the first electrode layer 171A may also be disposed on the mask layer 103 and may electrically connect between the adjacent light emitting structures 150.

Also, the second electrode 183A may be disposed on one side of the first electrode layer 171 A.

The first electrode layer 171A may electrically connect the second electrodes 183A and 183B to the light emitting structure 150 disposed at the first light emitting region L1 and may apply a voltage to the upper portion 150B and the lower portion 150A of the light emitting structure 150.

In FIG. 11, the second electrode layer 171B included in the second light emitting region L2 may be disposed on the light emitting structure 150 disposed on the second light emitting region L2. Specifically, the second electrode layer 171B may be disposed to surround the light emitting structure 150. At this point, the second electrode layer 171B may be disposed at only the lower portion 150A of the light emitting structure 150. And the second electrode layer 171B may also be disposed on the mask layer 103 and may electrically connect between the adjacent light emitting structures 150.

Also, the second electrode 183B may be disposed on one side of the second electrode layer 171B.

The second electrode layer 171B may electrically connect the second electrode 183B to the light emitting structure 150 disposed at the second light emitting region L2 and may apply a voltage to only the lower portion 150A of the light emitting structure 150.

Both of the upper portion 150B and the lower portion 150A of the light emitting structure 150 included in the first light emitting region L1 may emit light due to a structural difference between the first electrode layer 171A and the second electrode layer 171B. In the light emitting structure 150 disposed on the second light emitting region L2, only the lower portion 150A may emit light intensively. Therefore, the first light emitting region L1 and the second light emitting region L2 may emit light of different wavelength bands.

The electrode layer 171 of the first embodiment may emit light of various wavelength bands by applying different electric fields to each of the light emitting regions through a structural change of the electrode layer 171 without any additional configuration. Accordingly, the light emitting device 100 of the first embodiment has an advantage of emitting white light having high efficiency and high color rendering property.

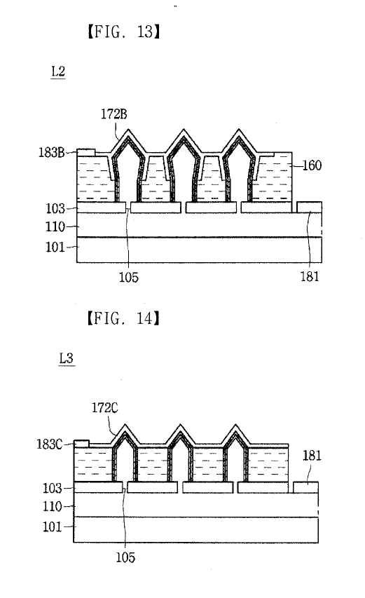

FIG. 12 is a side cross-sectional view of a first light emitting region L1 according to a second embodiment, FIG. 13 is a side cross-sectional view of a second light emitting region L2 according to the second embodiment, and FIG. 14 is a side cross-sectional view of a third light emitting region L3.

Referring to FIGS. 12 to 14, an electrode layer 172 of the second embodiment may have a different structure for each of the light emitting regions and thus may emit light of a different wavelength band in each of the light emitting regions. The electrode layer 172 of the second embodiment may include a first electrode layer 172A included in the first light emitting region L1, a second electrode layer 172B included in the second light emitting region L2 and a third electrode layer 172C included in the third light emitting region L3. And each of the electrode layers 172 may be electrically connected to the second electrodes 183A, 183B and 183C.

As shown in FIG. 12, the first electrode layer 172A may be disposed to surround the upper and lower portions 150A of the light emitting structure 150. And the first electrode layer 172A may have a different thickness according to an arrangement position thereof. For example, the first electrode layer 172A of the embodiment may have the largest thickness at a branch point between the upper portion 150B and the lower portion 150A of the light emitting structure 150, and the thickness thereof may be decreased as a distance from the branch point is increased.

The first electrode layer 172A may evenly apply a voltage to the upper and lower portions 150A of the light emitting structure 150 and may allow the light emitting structure 150 included in the first light emitting region L1 to emit light of a first wavelength band.

As shown in FIG. 13, the second electrode layer 172B may be disposed to surround a part of the upper portion 150B and the lower portion 150A of the light emitting structure 150. Specifically, the second electrode layer 172B may become gradually thinner from the branch point which divides the upper part 150B and the lower part 150A toward the lower part 150A and may not be formed at the lowermost portion of the light emitting structure 150. And the second electrode layer 172B may have a different thickness according to an arrangement position thereof. For example, the second electrode layer 172B of the embodiment may have the largest thickness at the branch point between the upper portion 150B and the lower portion 150A of the light emitting structure 150, and the thickness thereof may be decreased as a distance from the branch point is increased.

The second electrode layer 172B may apply a voltage to only a part of the upper portion 150B and the lower portion 150A of the light emitting structure 150 and may allow the light emitting structure 150 included in the second light emitting region L2 to emit light of a second wavelength band.

As shown in FIG. 14, the third electrode layer 172C may be disposed to surround the upper portion 150B of the light emitting structure 150.

The third electrode layer 172C may apply a voltage to only the upper portion 150B of the light emitting structure 150 and may allow the light emitting structure 150 included in the third light emitting region L3 to emit light of a third wavelength band.

The electrode layer 172 of the second embodiment may emit light of various wavelength bands by applying different electric fields to each of the light emitting regions through a structural change of the electrode layer 172 without any additional configuration. Accordingly, the light emitting device 100 of the second embodiment has an advantage of emitting white light having high efficiency and high color rendering property.

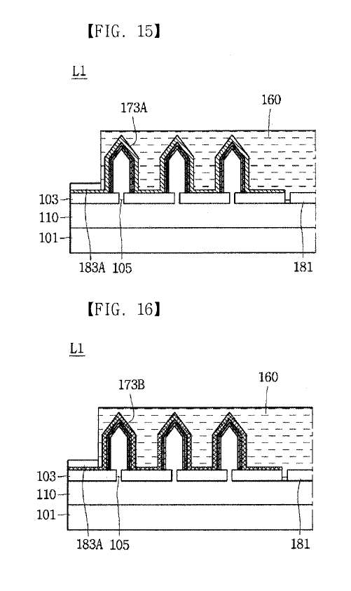

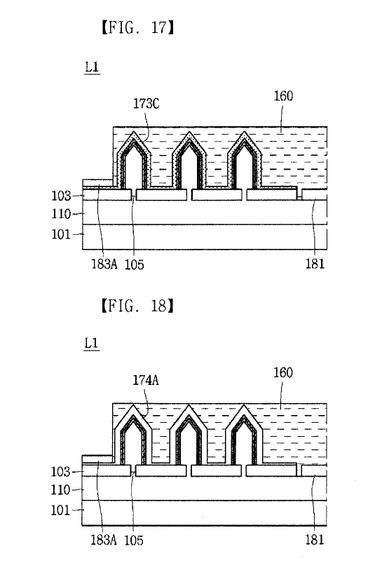

FIG. 15 is a side cross-sectional view of a first light emitting region L1 according to a third embodiment, FIG. 16 is a side cross-sectional view of a second light emitting region L2 according to the third embodiment, and FIG. 17 is a side cross-sectional view of a third light emitting region L3 according to the third embodiment.

Referring to FIGS. 15 to 17, an electrode layer 173 of the third embodiment may have a different structure for each of the light emitting regions and thus may emit light of a different wavelength band in each of the light emitting regions. The electrode layer 173 of the third embodiment may include a first electrode layer 173A included in the first light emitting region L1, a second electrode layer 173B included in the second light emitting region L2 and a third electrode layer 173C included in the third light emitting region L3. And each of the electrode layers 173 may be electrically connected to the second electrodes 183A, 183B and 183C. And each of the electrode layers 173 may be disposed to surround the light emitting structures 150 included in the light emitting regions, respectively.

As shown in FIG. 15, the first electrode layer 173A may be disposed to surround the upper and lower portions 150A of the light emitting structure 150. And the first electrode layer 173A may be formed of a material having relatively low electrical conductivity. For example, the first electrode layer 173A may include at least one of TiO₂, Ga₂O₃, MgIn₂O₄, GaInO₃, CdSb₂O₆, Zn₂SnO₄ and ZnSnO₃.

As shown in FIG. 16, the second electrode layer 173B may be disposed to surround the upper and lower portions 150A of the light emitting structure 150. And the second electrode layer 173B may be formed of a material having electrical conductivity which is relatively higher than that of the first electrode layer 173A. For example, the second electrode layer 173B may include at least one of SnO₂, Zn₂In₂O₅, Zn₃In₂O₆, In₄Sn₃O₂, CdIn₂O₄, CdSnO₄ and CdSnO₃.

As shown in FIG. 17, the third electrode layer 173C may be disposed to surround the upper and lower portions 150A of the light emitting structure 150.

And the third electrode layer 173C may be formed of a material having electrical conductivity which is relatively higher than that of the second electrode layer 173B. For example, the third electrode layer 173C may include at least one of ZnO, CdO and In₂O₃.

In the electrode layer 173 of the third embodiment, since the electrode layer 173 formed of a different material is disposed at each of the light emitting regions, each of the light emitting structures 150 may have an electric field of a different intensity even when the second electrodes 183A, 183B and 183C apply the same voltage to each of the electrode layers 173. Therefore, the light emitting structures 150 included in the light emitting regions may emit light of different wavelength bands.

For example, the first light emitting region L1 may emit red light because the electric field is formed with low intensity. And the second light emitting region L2 may emit green and/or yellow light because the electric field is formed with middle intensity. And, the third light emitting region L3 may emit blue light because the electric field is formed with high intensity.

The electrode layer 173 of the third embodiment may emit light of various wavelength bands by applying different electric fields to each of the light emitting regions through a structural change of the electrode layer 173 without any additional configuration. Accordingly, the light emitting device 100 of the third embodiment has an advantage of emitting white light having high efficiency and high color rendering property.

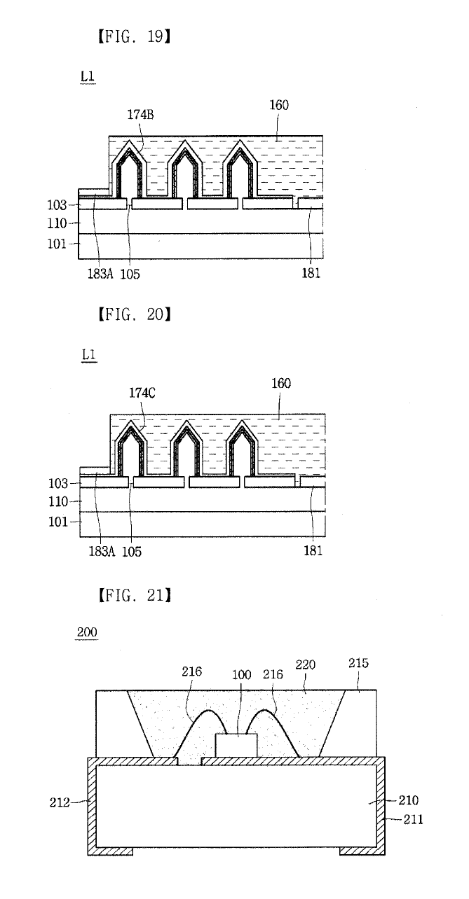

FIG. 18 is a side cross-sectional view of a first light emitting region L1 according to a fourth embodiment, FIG. 19 is a side cross-sectional view of a second light emitting region L2 according to the fourth embodiment, and FIG. 20 is a side cross-sectional view of a third light emitting region L3 according to the fourth embodiment.

Referring to FIGS. 18 to 20, an electrode layer 174 of the fourth embodiment may have a different structure for each of the light emitting regions and thus may emit light of a different wavelength band in each of the light emitting regions. The electrode layer 174 of the fourth embodiment may include a first electrode layer 174A included in the first light emitting region L1, a second electrode layer 174B included in the second light emitting region L2 and a third electrode layer 174C included in the third light emitting region L3. And each of the electrode layers 174 may be electrically connected to the second electrodes 183A, 183B and 183C. And each of the electrode layers 174 may be disposed to surround the light emitting structures 150 included in the light emitting regions, respectively.

As shown in FIG. 18, the first electrode layer 174A may be disposed to surround the upper and lower portions 150A of the light emitting structure 150 in the first light emitting region L1. And the first electrode layer 174A may have a relatively large thinness. For example, the thickness of the first electrode layer 174A of the embodiment may be formed to be more than 100 nm.

As shown in FIG. 19, the second electrode layer 174B may be disposed to surround the upper and lower portions 150A of the light emitting structure 150 in the second light emitting region L2. And the second electrode layer 174B may have a thinness which is smaller than that of the first electrode layer 174A. For example, the thickness of the second electrode layer 174B of the embodiment may be formed to be 20 to 100 nm.

As shown in FIG. 20, the third electrode layer 174C may be disposed to surround the upper and lower portions 150A of the light emitting structure 150 in the third light emitting region L3. And the third electrode layer 174C may have a thinness which is smaller than that of the second electrode layer 174B. For example, the thickness of the third electrode layer 174C of the embodiment may be formed to be less than 20 nm.

Since the thickness of the electrode layer 174 is inversely proportional to resistance of the electrode layer 174, each of the light emitting structures 150 may have an electric field of a different intensity even when the second electrodes 183A and 183B apply the same voltage to each of the electrode layers 174. Therefore, the light emitting structures 150 included in the light emitting regions may emit light of different wavelength bands.

For example, the first light emitting region L1 may emit blue light. And the second light emitting region L2 may emit green and/or yellow light. And the third light emitting region L3 may emit red light.

The electrode layer 174 of the fourth embodiment may emit light of various wavelength bands by applying different electric fields to each of the light emitting regions through a structural change of the electrode layer 174 without any additional configuration. Accordingly, the light emitting device 100 of the fourth embodiment has an advantage of emitting white light having high efficiency and high color rendering property.

FIG. 21 is a view illustrating a package of the light emitting device 100 having the light emitting device 100 of FIG. 2.

Referring to FIG. 21, a package 200 of a light emitting device 100 includes a body 210, a first lead electrode 211 and a second lead electrode 212 of which a part is disposed at the body 210, a light emitting device 100 which is electrically connected to the first lead electrode 211 and the second lead electrode 212, and a molding member 220 which surrounds the light emitting device 100 on the body 210.

The body 210 may be formed to include a silicone material, a synthetic resin material or a metallic material. The body 210 includes a reflecting portion 215 which has a cavity therein and an inclined surface therearound when seen from an upper side.

The first lead electrode 211 and the second lead electrode 212 are electrically separated from each other and may be formed to pass through an inside of the body 210. That is, one parts of the first lead electrode 211 and the second lead electrode 212 may be disposed inside the cavity and the other parts thereof may be disposed outside the body 210.

The first lead electrode 211 and the second lead electrode 212 may supply electric power to the light emitting device 100, may increase the optical efficiency by reflecting light generated from the light emitting device 100 and may exhaust heat generated from the light emitting device 100 to an outside.

The light emitting device 100 may be installed on the body 210 or may be installed on the first lead electrode 211 and/or the second lead electrode 212. A wire 216 connected to the light emitting device 100 may be electrically connected to the first lead electrode 211 and the second lead electrode 212, but the present invention is not limited thereto.

The molding member 220 may surround the light emitting device 100 and may protect the light emitting device 100. Also, the molding member 220 may include a phosphor, and a wavelength of the light emitted from the light emitting device 100 may be varied by the phosphor.

The light emitting device 100 and the package of the light emitting device 100 according to the embodiment may be applied to a light unit. The light unit may include a structure in which a plurality of light emitting devices 100 or a plurality of packages of the light emitting device 100 are arrayed and may include an illumination lamp, a traffic light, a vehicle headlight, an electric sign board, and so on.

The characteristics, structures and effects described in the embodiments above are included in at least one embodiment but are not limited to one embodiment. Furthermore, the characteristic, structure, and effect illustrated in each embodiment may be combined or modified for other embodiments by a person skilled in the art. Thus, it would be construed that contents related to such a combination and such a variation are included in the scope of the present invention.

Embodiments are mostly described above. However, they are only examples and do not limit the present invention. A person skilled in the art may appreciate that several variations and applications not presented above may be made without departing from the essential characteristic of embodiments. For example, each component particularly represented in embodiments may be varied. In addition, it should be construed that differences related to such a variation and such an application are included in the scope of the present invention defined in the following claims.

1. A light emitting device comprising:
a conductive semiconductor layer divided into at least two or more light emitting regions;
a plurality of light emitting structures on the conductive semiconductor layer;
an electrode layer on the plurality of light emitting structures;
a second electrode electrically connected to the electrode layer; and
a first electrode electrically connected to the conductive semiconductor layer,
wherein each of the light emitting structures includes a rod-shaped first conductivity type semiconductor, an active layer configured to surround the first conductivity type semiconductor and a second conductivity type semiconductor configured to surround the active layer, and
each of the light emitting structures has at least two or more outer surfaces having different extending directions with respect to an upper surface of the conductive semiconductor layer,
wherein the plurality of light emitting structures are connected by the electrode layer, and
wherein a width of each the rod-shaped first conductivity type semiconductor is less than a distance between adjacent the rod-shaped first conductivity type semiconductors.

2. The light emitting device of claim 1, wherein each of the light emitting structures has one of a lower portion having a hexagonal column shape, a dodecagonal column shape or a polygonal column shape.

3. The light emitting device of claim 1, wherein each of the light emitting structures has one of an upper portion having a hexagonal pyramid shape, a dodecagonal pyramid shape or a polygonal pyramid shape.

4. The light emitting device of claim 1, wherein each of the light emitting structures includes a first outer surface which extends upward in a direction perpendicular to the upper surface of the conductive semiconductor layer and a second outer surface which extends upward at a predetermined angle with respect to the upper surface of the conductive semiconductor layer.

5. The light emitting device of claim 4, wherein each of the light emitting structures includes a third outer surface which is in parallel with the upper surface of the conductive semiconductor layer.

6. The light emitting device of claim 1, wherein the conductive semiconductor layer includes a first light emitting region which emits light of a first wavelength band and a second light emitting region which emits light of a second wavelength band.

7. The light emitting device of claim 6, wherein the first light emitting region and the second light emitting region of the conductive semiconductor layer share the first electrode.

8. The light emitting device of claim 6, wherein the electrode layer includes a first electrode layer which is disposed on an upper portion and a lower portion of the light emitting structure of the first light emitting region and a second electrode layer which is disposed on a lower portion of the light emitting structure of the second light emitting region.

9. The light emitting device of claim 6, wherein the conductive semiconductor layer further includes a third light emitting region which emits light of a third wavelength band.

10. The light emitting device of claim 9, wherein the electrode layer includes a first electrode layer which is disposed on the light emitting structure of the first light emitting region, a second electrode layer which is disposed on the second light emitting region and a third electrode layer which is disposed on the third light emitting region.

11. The light emitting device of claim 10, wherein the first electrode layer is disposed at an upper portion and a lower portion of the light emitting structure of the first light emitting region, and the second electrode layer is disposed at a part of an upper portion and a lower portion of the light emitting structure of the second light emitting region, and the third electrode layer is disposed at an upper portion of the light emitting structure of the third light emitting region.

12. The light emitting device of claim 10, wherein electrical conductivity of the first electrode layer is lower than that of the second electrode layer, and the electrical conductivity of the second electrode layer is lower than that of the third electrode layer.

13. The light emitting device of claim 10, wherein the first electrode layer is formed of one of TiO₂, Ga₂O₃, MgIn₂O₄, GaInO₃, CdSb₂O₆, Zn₂SnO₄ or ZnSnO₃, and the second electrode layer is formed of one of SnO₂, Zn₂In₂O₅, Zn₃In₂O₆, In₄Sn₃O₂, CdIn₂O₄, CdSnO₄ or CdSnO₃, and the third electrode layer is formed of one of ZnO, CdO or In₂O₃.

14. The light emitting device of claim 10, wherein a thickness of the first electrode layer is thicker than that of the second electrode layer, and the thickness of the second electrode layer is thicker than that of the third electrode layer.

15. The light emitting device of claim 14, wherein the thickness of the first electrode layer is more than 100 nm, and the thickness of the second electrode layer is 20 to 100 nm, and the thickness of the third electrode layer is less than 20 nm.

16. A light emitting device comprising:
a conductive semiconductor layer divided into at least two or more light emitting regions;
a plurality of light emitting structures having rod shapes on the conductive semiconductor layer;
an electrode layer on the plurality of light emitting structures;
a second electrode electrically connected to the electrode layer; and
a first electrode electrically connected to the conductive semiconductor layer,
wherein the light emitting structures included in the light emitting regions of the conductive semiconductor layer have different electric fields and emit light of different wavelength bands when being operated
wherein each of the light emitting structures includes a rod-shaped first conductivity type semiconductor, an active layer configured to surround the first conductivity type semiconductor and a second conductivity type semiconductor configured to surround the active layer, and
each of the light emitting structures has at least two or more outer surfaces having different extending directions with respect to an upper surface of the conductive semiconductor layer,
wherein the active layer is disposed on a top surface and a side surface of the rod-shaped first conductivity type semiconductor, and
wherein the second conductivity type semiconductor is disposed a top surface and a side surface of the active layer.

17. A lighting system comprising a light emitting module having the light emitting device of claim 1.

18. The light emitting device of claim 16, wherein the second electrode is electrically connected to the top surface and the side surface of the second conductivity type semiconductor layer.

19. The light emitting device of claim 16, wherein the electrode layer is electrically connected to the top surface and the side surface of the second conductivity type semiconductor layer.

20. The light emitting device of claim 16,
wherein the plurality of light emitting structures are connected by the electrode layer, and
wherein a width of each the rod-shaped first conductivity type semiconductor is less than a distance between adjacent the rod-shaped first conductivity type semiconductors.
